(19) United States
(12) Patent Application Publication
(10) Pub. No.: US 2016/0087133 A1
(43) Pub. Date: Mar. 24, 2016

(54) LIGHT CONCENTRATION DEVICE

(71) Applicant: ENI S.P.A., Roma (IT)

(72) Inventors: Roberto FUSCO, Novara (NO) (IT); Marco LISCIDINI, Pavia (IT); Sthy Warren FLORES DAORTA, Milano (IT); Lucio ANDREANI, Pavia (IT)

(73) Assignee: ENI S.P.A., Roma (IT)

(21) Appl. No.: 14/785,934

(22) PCT Filed: Jun. 25, 2014
(86) PCT No.: PCT/IB2014/062584

§ 371 Date: Oct. 21, 2015

(30) Foreign Application Priority Data
Jun. 26, 2013 (IT) MI2013A 001062

(51) Int. Cl. H01L 31/055

(52) U.S. Cl. CPC H01L 31/055

(57) ABSTRACT

Light concentration device comprising: —a primary luminescent solar concentrator (LSC) having a polygonal, circular or elliptic form, comprising at least one photoluminescent compound having a first absorption range and a first emission range; —at least a secondary luminescent solar concentrator (LSC) positioned outside said primary luminescent solar concentrator (LSC), said secondary luminescent solar concentrator (LSC) comprising at least one photoluminescent compound having a second absorption range superimposable to said first emission range and a second emission range. Said light concentration device can be advantageously used in photovoltaic devices (or solar devices) such as, for example, photovoltaic cells (or solar cells), photoelectrolytic cells. Said light concentration device can also be advantageously used in photovoltaic windows.

The present invention relates to a light concentration device.

More specifically, the present invention relates to a light concentration device comprising a primary luminescent solar concentrator (LSC) having a polygonal, circular or elliptic form, and at least a secondary luminescent solar concentrator (LSC) positioned outside said primary luminescent solar concentrator (LSC).

Said light concentration device can be advantageously used in photovoltaic devices (or solar devices) such as, for example, photovoltaic cells (or solar cells), photoelectrolytic cells. Said light concentration device can also be advantageously used in photovoltaic windows.

The present invention also relates to a photovoltaic device (or solar device) comprising said light concentration device wherein at least one photovoltaic cell (or solar cell) is positioned at the smaller outer sides of said secondary luminescent solar concentrator (LSC).

In the state of the art, one of the main limits in exploiting the energy of solar radiations is represented by the capacity of photovoltaic devices (or solar devices) of optimally absorbing only radiations having wavelengths within a narrow spectrum range.

For example, against a spectrum range of solar radiation extending from wavelengths of about 300 nm to wavelengths of about 2,500 nm, photovoltaic cells (or solar cells) based on crystalline silicon, for example, have an optimum absorption area (effective spectrum) within the range of 900 nm-1,100 nm, whereas polymer photovoltaic cells (or solar cells) can be damaged when exposed to radiations with wavelengths lower than about 500 nm, due to induced photodegradation phenomena which become significant below this limit. The efficiency of the photovoltaic devices (or solar devices) of the state of the art is typically at its maximum within the spectrum region ranging from 570 nm to 680 nm (yellow-orange).

The drawbacks previously indicated imply a limited external quantum efficiency (EQE) of the photovoltaic device (or solar device), defined as the ratio between the number of electron-hole pairs generated in the semiconductor material of the photovoltaic device (or solar device) and the number of photons incident on the photovoltaic device (or solar device).

In order to improve the external quantum efficiency (EQE) of photovoltaic devices (or solar devices), devices have been developed, i.e. luminescent solar concentrators (LSCs) which, when interposed between the light radiation source (the sun) and the photovoltaic device (or solar device), selectively absorb incident radiations having wavelengths outside the effective spectrum of the photovoltaic device (or solar device), emitting the energy absorbed in the form of photons having a wavelength within the effective spectrum. When the energy of the photons emitted by a luminescent solar concentrator (LSC) is higher than that of the incident photons, the photoluminescent process, comprising the absorption of the solar radiation and the subsequent emission of photons having a lower wavelength, is also called “up-conversion” process. When, on the contrary, the energy of the photons emitted by a luminescent solar concentrator (LSC) is lower than that of the incident photons, the photoluminescent process is called “down-shifting” process.

The luminescent solar concentrators (LSCs) known in the state of the art are typically in the form of a sheet and comprise a matrix made of material transparent, as such, to the radiations of interest (for example, transparent glass or transparent polymeric materials), one or more photoluminescent compounds generally selected, for example, from organic compounds, metal complexes, inorganic compounds (for example, rare earth), “quantum dots” (QDs). Due to the optical phenomenon of total reflection, the radiation emitted by the photoluminescent compounds is “guided” towards the thin edges of said sheet where it is concentrated on photovoltaic cells (or solar cells) positioned thereon. In this way, extensive surfaces of low-cost materials (called sheet) can be used for concentrating the light on small surfaces of high-cost materials [photovoltaic cells (or solar cells)].

Said photoluminescent compounds can be deposited on the matrix made of transparent material in the form of a thin film, or they can be dispersed inside the transparent matrix. Alternatively, the transparent matrix can be directly functionalized with photoluminescent chromophore groups.

A photoluminescent compound should have numerous characteristics for being advantageously used in the construction of luminescent solar concentrators (LSCs) and these are not always compatible with each other.

First of all, the frequency of the radiation emitted by fluorescence must correspond to an energy higher than the threshold value below which the semiconductor, which represents the core of the photovoltaic cell (or solar cell), is no longer able to function.

Secondly, the absorption spectrum of the photoluminescent compound should be as extensive as possible, so as to absorb most of the incident solar radiation and then re-emit it at the desired frequency.

It is also desirable that the absorption of the solar radiation be extremely intense, so that the photoluminescent compound can exert its function at the lowest possible concentrations, avoiding the use of the same in massive quantities.

Furthermore, the absorption process of solar radiation and of its subsequent emission at lower frequencies, must take place with the highest possible efficiency, minimizing the so-called non-radiative losses, often collectively indicated with the term “thermalization”: the efficiency of the process is measured by its quantum yield.

Finally, the absorption and the emission bands must have a minimum overlapping, as otherwise the radiation emitted by a molecule of the photoluminescent compound would be absorbed and at least partially scattered by the adjacent molecules. Said phenomenon, generally called self-absorption, inevitably leads to a significant loss in efficiency. The difference between the frequencies of the peak with the lower frequency of the absorption spectrum and the peak of the radiation emitted, is normally indicated as Stokes “shift” and measured in nm (i.e. it is not the difference between the two frequencies that is measured, but the difference between the two wavelengths which correspond to them). Said Stokes shifts must be sufficiently high as to guarantee the minimum overlapping possible between the absorption bands and the emission bands, consequently obtaining high efficiencies of the luminescent solar concentrators (LSCs), bearing in mind the necessity, already mentioned, that the frequency of the radiation emitted corresponds to an energy higher than the threshold value below which the photovoltaic cell (or solar cell) is not able to function.

Further details relating to the above luminescent solar concentrators (LSCs) can be found, for example, in: Weber W. H. et al., “Applied Optics” (1976), Vol. 15, Issue 10, pages 2299-2300; Levitt J. A. et al., “Applied Optics” (1977), Vol. 16, Issue 10, pages 2684-2689; Reisfeld R. et al., “Nature” (1978), Vol. 274, pages 144-145; Goetzberger A. et al., “Applied Physics” (1978), Vol. 16, Issue 4, pages 399-404.

The main objective of the luminescent solar concentrators (LSCs) is to reduce the quantity of high-cost materials [i.e. the quantity of materials used for the construction of photovoltaic cells (or solar cells)]. Furthermore, the use of luminescent solar concentrators (LSCs) makes it possible to operate with both direct and scattered light, contrary to the use of silicon photovoltaic panels (or solar panels) whose performances greatly depend on the direction from which the light arrives: said luminescent solar concentrators (LSCs) can therefore be used in urban integration contexts as passive elements, i.e. elements which do not require solar trackers, having various colours and forms. Opaque luminescent solar concentrators (LSCs), for example, could be used in walls and roofs whereas semi-transparent luminescent solar concentrators (LSCs) could be used as windows.

Further details relating to the above uses can be found, for example, in: Chatten A. J. et al., “Proceeding Nanotech Conference and Expo” (2011), Boston, USA, pages 669-670; Dedbije M. G., “Advanced Functional Materials” (2010), Vol. 20, Issue 9, pages 1498-1502; Dedbije M. G. et al., “Advanced Energy Materials” (2012), Vol. 2, pages 12-35.

A further application of the luminescent solar concentrators (LSCs) are the so-called Luminescent Spectrum Splitters (LSSs). In this case, small luminescent solar concentrators (LSCs) positioned in series, each of which has a maximum absorption at different wave-lengths and divides the light previously concentrated by another solar concentrator such as, for example, an optical solar concentrator, positioned in front of said series. The advantages of these Luminescent Spectrum Splitters (LSSs) consists in the fact that the light is guided through short distances. Further details relating to these Luminescent Spectrum Splitters (LSSs) can be found, for example, in Fischer B. et al., “Solar Energy Materials & Solar Cells” (2011), Vol. 95, pages 1741-1755.

Alternatively, the luminescent solar concentrators (LSCs) can be used for producing light, exploiting solar radiations and reducing energy consumption as, for example, in buildings for office use: the concentrated light can in fact be transported through optical cables into said buildings therefore allowing an energy saving. Further details relating to said use can be found, for example, in: Earp A. A. et al., “Solar Energy Materials & Solar Cells” (2004), Vol. 84, pages 411-426; Earp A. A. et al., “Solar Energy” (2004), Vol. 76, pages 655-667.

Research for improving the performances of luminescent solar concentrators (LSCs) has been directed towards various aspects such as, for example: (i) reducing the self-absorption phenomenon; (ii) increasing of the absorption of the solar light; (iii) making the light emitted coincide with the spectral region having the greatest quantum efficiency of the photovoltaic cell (or solar cell); (iv) reducing the area of the photovoltaic cells (or solar cells).

Goetzberger et al., for example, in “Applied Physics” (1979), Vol. 190, Issue 1, pages 53-58, disclose that a greater concentration of the solar light in luminescent solar concentrators (LSCs) can be obtained by applying a taper to the edges in which a light is concentrated, having a higher refraction index and reflecting surfaces, so as to reduce the size of the photovoltaic cell (or solar cell) positioned on said edges. By tapering said edges, it is therefore possible to increase the concentration factor and to improve the light distribution in the photovoltaic cell (or solar cell).

Goldschimidt et al., in “Physica Status Solidi A” (2008), Vol. 205, Issue 12, pages 2811-2821, provide a theoretical and experimental analysis of the application of filters which stop the photonic band positioned above the luminescent solar concentrators (LSCs), so as to increase the concentration efficiency of the photons.

Van Sark W. G. J. H. M. et al., in “Optics Express” (2008), Vol. 16, No. 26, pages 21773-21792, describe the possibility of using mirrors in order to guide the emission of the photoluminescent compounds (for example, dyes) used, towards the photovoltaic cell. They also disclose the fact that the light distribution on the edges of the luminescent solar concentrators (LSCs) is influenced by their form: their performances are in fact revealed in decreasing order for circular, hexagonal and rectangular forms, the latter being the most common and adaptable to different applications.

The various performances of the luminescent solar concentrators (LSCs) in relation to their form are also cited by Sidrach de Cardona M. et al., in “Solar Cells” (1985), Vol. 15, pages 225-230.

American patent U.S. Pat. No. 4,227,939 describes a device for light concentration comprising a transparent substrate having a higher refraction index than that of the environment surrounding it, and having a front surface which receives the incident light, a rear surface, an edge which emits the light absorbed and containing a uniform concentration of at least one fluorescent dye capable of absorbing the incident light and of emitting it by fluorescence, said incident light being sent through said substrate to said edge, characterized in that said substrate has a concave front surface and the ratio between the curvature radius of the rear surface and the curvature radius of the front surface is higher than 1. The particular geometrical form of said device is said to be capable of increasing and uniforming the light sent to said edge.

McIntosh K. R. et al., in “Applied Physics B” (2007), Vol. 16, No. 26, pages 285-290, provide a comparison between luminescent solar concentrators (LSCs) in the form of parallel tubes and in rectangular form which shows that the former allow an increase in the light concentration and a reduction of losses during surface reflections.

Banaei E. et al., in a work presented at Techconnect Word, Clean Technology 2011, Boston, USA, June 13-16, describe luminescent solar concentrators (LSCs) based on optical fibres. Various parameters such as, for example, structure of optical fibres, form and dimension of optical fibres, photoluminescent compounds and their concentration in said optical fibres, are also described and evaluated.

American patent application US 2011/0284729 describes fibres for collecting optical energy (for example, solar energy) comprising: a core which comprises active elements which absorb light at a wavelength or range of wavelengths and emit light at a wavelength or range of wavelengths; a guiding structure which guides and emits light along the length of the fibre; and a cladding which surrounds the core. Said patent application also describes a system for collecting optical energy comprising said fibres for collecting optical energy (for example, solar energy) and photovoltaic cells coupled with said fibres. The above mentioned fibres for collecting optical energy are said to have a good cost-efficiency ratio as they are capable of minimizing the surface of the photovoltaic cells used.

As indicated above, as the main purpose of luminescent solar concentrators (LSCs) is to reduce the quantity of high-cost material [i.e. the quantity of material used for the construction of photovoltaic cells (or solar cells)], the study of new luminescent solar concentrators (LSCs) capable of further reducing the quantity of said materials, is still of considerable interest.

The Applicant has therefore considered the problem of finding a light concentration device which is capable of further reducing the quantity of high-cost material [i.e. the quantity of material used for the construction of photovoltaic cells (or solar cells)].

The Applicant has now found a light concentration device comprising a primary luminescent solar concentrator (LSC) having a polygonal, circular or elliptic form, and at least a secondary luminescent solar concentrator (LSC) positioned outside said primary luminescent solar concentrator (LSC), said secondary luminescent solar concentrator (LSC), which is capable of further reducing the quantity of high-cost material [i.e. the quantity of material used for the construction of photovoltaic cells (or solar cells)]. Said secondary luminescent solar concentrator (LSC) positioned outside said primary luminescent solar concentrator (LSC), in fact, has reduced dimensions with respect to those of said primary luminescent solar concentrator (LSC): the photovoltaic cells (or solar cells) which are positioned at the smaller outer edges of said secondary luminescent solar concentrator (LSC) therefore have smaller dimensions. Said light concentration device can in fact be advantageously used in solar devices (i.e. devices for exploiting solar energy) such as, for example, photovoltaic cells (or solar cells), photoelectrolytic cells. Furthermore, unlike the luminescent solar concentrators (LSCs) known in the art, in which the light concentration factor theoretically (various losses due for example to phenomena relating to self-absorption, internal reflection, chemical instability of the photoluminescent compound(s), parasitic absorption of the matrix made of a transparent material, should in fact be taken into consideration), increases linearly with an increase in the dimension of said luminescent solar concentrators (LSCs), in said light concentration device, bearing in mind the various losses indicated above, the light concentration factor increases linearly with the square of the dimensions of said primary luminescent solar concentrator (LSC). Furthermore, said light concentration device can reduce the absorption bandwidth required by the photovoltaic cells (or solar cells), thus allowing various types of photovoltaic cells (or solar cells) to be used, such as, for example, inorganic photovoltaic cells (or solar cells) which use, in particular, high-purity crystalline silicon, organic photovoltaic cells (or solar cells) which use alternative materials of the organic type having a conjugated, oligomeric or polymeric structure. Said light concentration device can also be advantageously used in photovoltaic windows.

An object of the present invention therefore relates to a light concentration device comprising:
a primary luminescent solar concentrator (LSC) having a polygonal, circular or elliptic form, comprising at least one photoluminescent compound having a first absorption range and a first emission range;
at least a secondary luminescent solar concentrator (LSC) positioned outside said primary luminescent solar concentrator (LSC), said secondary luminescent solar concentrator (LSC) comprising at least one photoluminescent compound having a second absorption range superimposable to said first emission range and a second emission range.

For the aim of the present description and of the following claims, the definitions of the numerical ranges always comprise the extremes unless otherwise specified.

For the aim of the present description and of the following claims, the term “comprising” also includes the terms “which essentially consists of” or “which consists of”.

According to a preferred embodiment of the present invention, said primary luminescent solar concentrator (LSC) has a polygonal form and said secondary luminescent solar concentrator (LSC) can be positioned outside at least one of the sides of said primary luminescent solar concentrator (LSC).

According to a further preferred embodiment of the present invention, said primary luminescent solar concentrator (LSC) has a polygonal form and said secondary luminescent solar concentrator (LSC) can be positioned outside more than one of the sides of said primary luminescent solar concentrator (LSC).

It should be noted that, for the aim of the present invention, said secondary luminescent solar concentrator (LSC) can have a length equal to the length of the outer side of the primary luminescent solar concentrator (LSC) on which it is positioned; or it can cover only a part of the outer side of the primary luminescent solar concentrator (LSC) on which it is positioned; or various secondary luminescent solar concentrators (LSCs) can be positioned on the length or on part of the length of said outer side, in contact with or spaced from each other.

According to a further preferred embodiment of the present invention, said secondary luminescent solar concentrator (LSC) can envelop at least a part of the outer perimeter of said primary luminescent solar concentrator (LSC).

It should be noted that, for the aim of the present invention, said secondary luminescent solar concentrator (LSC) can envelop at least 20%, preferably from 30% to 100%, of the total outer perimeter of said primary luminescent solar concentrator.

According to a preferred embodiment of the present invention, said primary luminescent solar concentrator (LSC) comprises a matrix made of a transparent material which can be selected, for example, from: transparent polymers such as, for example, polymethylmethacrylate (PMMA), polycarbonate (PC), polyisobutyl methacrylate, polyethyl methacrylate, polyallyl diglycol carbonate, polymethacrylimide, polycarbonate ether, styrene acrylonitrile, polystyrene, methyl-methacrylate styrene copolymers, polyether sulfone, polysulfone, cellulose triacetate, or mixtures thereof; transparent glass such as, for example, silica, quartz, alumina, titania, or mixtures thereof. Polymethylmethacrylate (PMMA) is preferred.

According to a preferred embodiment of the present invention, said photoluminescent compound having a first absorption range and a first emission range can be selected from photoluminescent compounds having an absorption range ranging from 290 nm to 700 nm, preferably ranging from 300 nm to 600 nm, and an emission range ranging from 390 nm to 800 nm, preferably ranging from 400 nm to 700 nm.

According to a preferred embodiment of the present invention, said photoluminescent compound having a first absorption range and a first emission range can be selected from benzothiadiazole compounds such as, for example, 4,7-di-(thien-2′-yl)-2,1,3-benzothiadiazole (DTB); acene compounds such as, for example, 9,10-diphenylanthracene (DPA); or mixtures thereof. Said photoluminescent compound having a first absorption range and a first emission range can preferably be selected from 4,7-di-(thien-2′-yl)-2,1,3-benzothiadiazole (DTB), 9,10-diphenylanthracene (DPA), or mixtures thereof, and is even more preferably 4,7-di-(thien-2′-yl)-2,1,3-benzothiadiazole (DTB). Benzothiadiazole compounds are described, for example, in Italian patent application MI2009A001796. Acene compounds are described, for example, in International patent application WO 2011/048458.

According to a preferred embodiment of the present invention, said photoluminescent compound having a first absorption range and a first emission range can be present in said primary luminescent solar concentrator (LSC) in a quantity ranging from 0.1 g per surface unit to 2 g per surface unit, preferably ranging from 0.2 g per surface unit to 1.5 g per surface unit, said surface unit referring to the surface of the matrix made of transparent material expressed in m².

According to a preferred embodiment of the present invention, said photoluminescent compound having a second absorption range superimposable to said first emission range and a second emission range, can be selected from photoluminescent compounds having an absorption range ranging from 400 nm to 700 nm, preferably ranging from 450 nm to 650 nm, and an emission range ranging from 450 nm to 900 nm, preferably ranging from 500 nm to 850 nm.

According to a preferred embodiment of the present invention, said secondary luminescent solar concentrator (LSC) comprises a matrix made of transparent material which can be selected, for example, from: transparent polymers such as, for example, polymethylmethacrylate (PMMA), polycarbonate (PC), polyisobutyl methacrylate, polyethyl methacrylate, polyallyl diglycol carbonate, polymethacrylimide, polycarbonate ether, styrene acrylonitrile, polystyrene, methyl-methacrylate styrene copolymers, polyether sulfone, polysulfone, cellulose triacetate, or mixtures thereof; transparent glass such as, for example, silica, quartz, alumina, titania, or mixtures thereof. Polymethylmethacrylate (PMMA) is preferred.

According to a further preferred embodiment of the present invention, said primary luminescent solar concentrator (LSC) and said secondary luminescent solar concentrator (LSC), comprise the same matrix made of transparent material.

According to a preferred embodiment of the present invention, said photoluminescent compound having a second absorption range superimposable to said first emission range and a second emission range can be selected from perylene compounds such as, for example, compounds known with their trade-name Lumogen® of Basf.

According to a preferred embodiment of the present invention, said photoluminescent compound having a second absorption range superimposable to said first emission range and a second emission range can be present in said secondary luminescent solar concentrator (LSC) in a quantity ranging from 0.1 g per surface unit to 2 g per surface unit, preferably ranging from 0.2 g per surface unit to 1.5 g per surface unit, said surface unit referring to the surface of the matrix made of transparent material expressed in m².

According to a further preferred embodiment of the present invention, said secondary luminescent solar concentrator (LSC) can be positioned at a distance ranging from 0.5 μm to 3 mm, preferably ranging from 1 μm to 2 mm, with respect to the outer perimeter of said primary luminescent solar concentrator (LSC).

Said primary luminescent solar concentrator (LSC) and said secondary luminescent solar concentrator (LSC), can be held together by a suitable frame or, alternatively, by a suitable optical glue having a refraction index which allows a good optical coupling (for example, silicone, epoxy resins).

In order to increase the light emitted by the primary luminescent solar concentrator (LSC), a primary luminescent solar concentrator (LSC) can be used, wherein at least part of the outer perimeter is rough.

For the aim of the present invention and of the following claims, the term “rough outer perimeter” refers to an outer perimeter having protrusions and cavities at a certain distance. The roughness can be measured by means of known techniques, such as, for example, Microscope Atomic Force (MFA) and/or profilometry.

According to a further preferred embodiment of the present invention, at least part of the outer perimeter of said primary luminescent solar concentrator (LSC) can be rough.

Alternatively, in order to increase the light absorbed by the secondary luminescent solar concentrator (LSC), reflecting mirrors can be positioned on at least part of the outer perimeter of said secondary luminescent solar concentrator (LSC).

According to a further preferred embodiment of the present invention, at least one reflecting mirror can be positioned on at least part of the outer perimeter of said secondary luminescent solar concentrator (LSC). Said reflecting mirror can be made of metallic material (for example, aluminium, silver) or of dielectric material (for example, Bragg reflectors).

As mentioned above, said light concentration device can be advantageously used for solar devices (i.e. devices for exploiting solar energy) such as, for example, photovoltaic cells (or solar cells).

A further objective of the present invention therefore relates to a photovoltaic device (or solar device) including a light concentration device comprising:
a primary luminescent solar concentrator (LSC) having a polygonal, circular or elliptic form, comprising at least one photoluminescent compound having a first absorption range and a first emission range;
at least a secondary luminescent solar concentrator (LSC) positioned outside said primary luminescent solar concentrator (LSC), said secondary luminescent solar concentrator (LSC) comprising at least one photoluminescent compound having a second absorption range superimposable to said first emission range and a second emission range;
at least one photovoltaic cell (or solar cell) positioned outside at least one of the smaller sides of said secondary luminescent solar concentrator (LSC).

It should be noted that, for the aim of the present invention, said second emission range is superimposable to the maximum quantum efficiency area of the photovoltaic cells (or solar cells) used.

The above-mentioned photoluminescent compounds can be used in both said primary luminescent solar concentrator (LSC) and in said secondary luminescent solar concentrator (LSC), in different forms.

If, for example, the transparent matrix is of the polymeric type, said at least one photoluminescent compound can be dispersed in the polymer of said transparent matrix, for example, by dispersion in the molten state, or by mass additivation, with the subsequent formation of a sheet comprising said polymer and said at least one photoluminescent compound, operating, for example, according to the so-called “casting” technique. Alternatively, said at least one photoluminescent compound and the polymer of said transparent matrix can be dissolved in at least one suitable solvent, obtaining a solution which is deposited on a sheet of said polymer, forming a film comprising said at least one photoluminescent compound and said polymer, operating, for example, with the use of a filmograph of the “Doctor Blade” type: said solvent is then left to evaporate. Said solvent can be selected, for example, from: hydrocarbons such as, for example, 1,2-dichloromethane, toluene, hexane; ketones such as, for example, acetone, acetyl acetone; or mixtures thereof.

If the transparent matrix is of the vitreous type, said at least one photoluminescent compound can be dissolved in at least one suitable solvent (which can be selected from those indicated above) obtaining a solution which is deposited on a sheet of said transparent matrix of the vitreous type, forming a film comprising said at least one photoluminescent compound operating, for example, with the use of a filmograph of the “Doctor Blade” type: said solvent is then left to evaporate.

Alternatively, a sheet comprising said at least one photoluminescent compound and said polymer obtained as described above, by dispersion in the molten state, or by mass additivation, and subsequent “casting”, can be enclosed between two sheets of said transparent matrix of the vitreous type (sandwich) operating according to the known lamination technique.

For the aim of the present invention, said primary luminescent solar concentrator (LSC) and said secondary luminescent solar concentrator (LSC) can be produced in the form of a sheet by mass additivation and subsequent “casting”, as described above. Said sheets can be subsequently coupled with the photovoltaic cells (or solar cells) so as to obtain the above-mentioned photovoltaic device (or solar device).

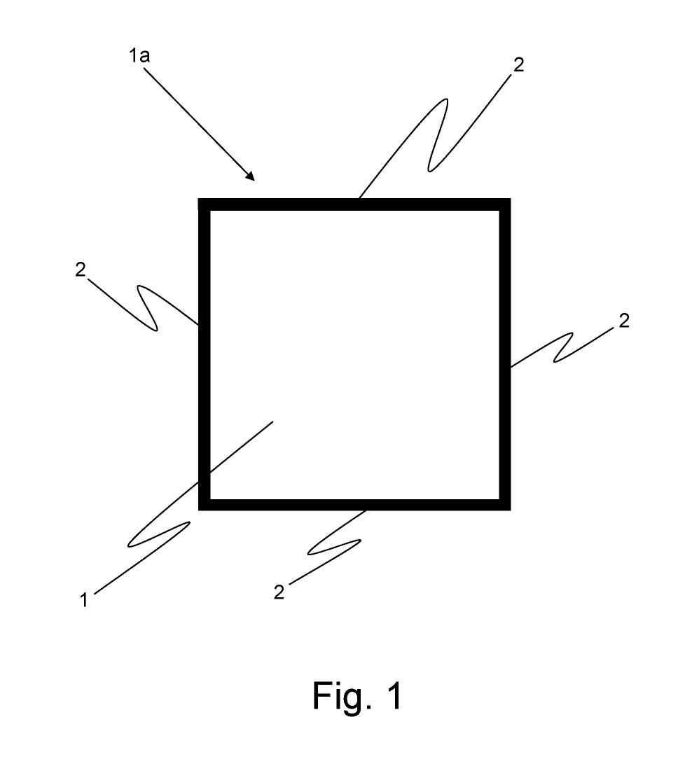

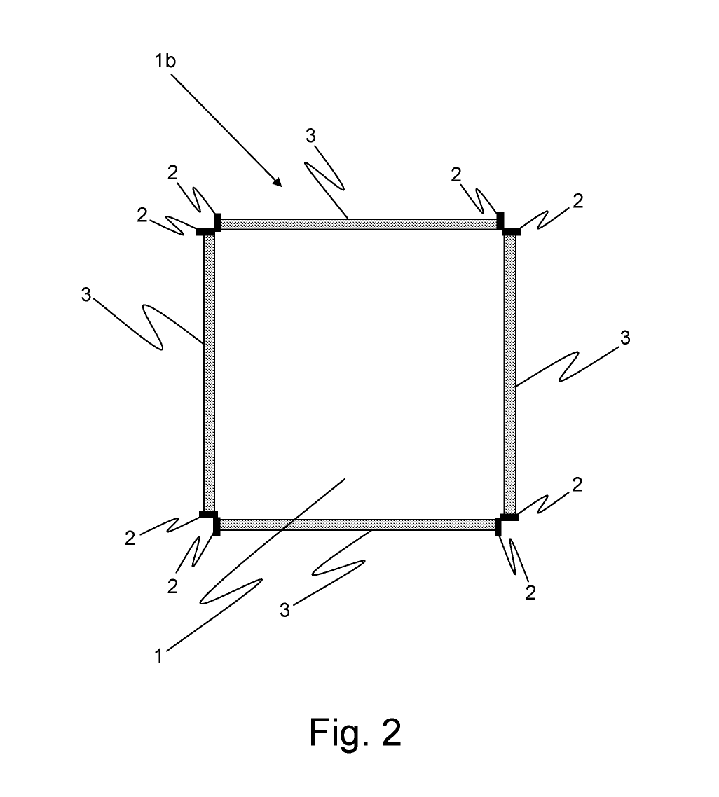

The present invention will be now illustrated in greater detail through an embodiment with reference to FIG. 1 and FIG. 2 provided hereunder, in which:

FIG. 1 represents a view from above (1a) of a photovoltaic device (or solar device) according to the known art;

FIG. 2 represents a view from above (1b) of a photovoltaic device (or solar device) according to the present invention.

In particular, FIG. 1 represents a view from above (1a) of a photovoltaic device (or solar device) according to the known art comprising a luminescent solar concentrator (LSC) (1) including at least one photoluminescent compound [e.g., 4,7-di-2-thienyl-2,1,3-benzothiadiazole (DTB), or a mixture of 4,7-di-2-thienyl-2,1,3-benzothiadiazole (DTB) with 9,10-diphenylanthracene (DPA)] and four photovoltaic cells (or solar cells) (2) positioned at the outer sides of said luminescent solar concentrator (LSC) (1).

FIG. 2 represents a view from above (1b) of a photovoltaic device (or solar device) according to the present invention, comprising: a primary luminescent solar concentrator (LSC) (1) comprising at least one photoluminescent compound having a first absorption range and a first emission range [e.g., 4,7-di-2-thienyl-2,1,3-benzothiadiazole (DTB), or a mixture of 4,7-di-2-thienyl-2,1,3-benzothiadiazole (DTB) with 9,10-diphenylanthracene (DPA)], four secondary luminescent solar concentrators (LSCs) (3) positioned at the outer sides of said primary luminescent solar concentrator (LSC) (1), each of said secondary luminescent solar concentrators comprising at least one photoluminescent compound having a second absorption range superimposable to said first emission range and a second emission range (e.g., Lumogen® F Red 305 of Basf), eight photovoltaic cells (or solar cells) (2) positioned at the smallest outer sides of each of said secondary luminescent solar concentrators (LSCs) (3).

Some illustrative and non-limiting examples are provided hereunder for a better understanding of the present invention and for its embodiment.

The 4,7-di-(thien-2′-yl)-2,1,3-benzothiadiazole (DTB) was obtained as described in patent application MI2010A001316.

### EXAMPLE 1

### Comparative

Photovoltaic cells IXYS-XOD17 having a surface of 1.2 cm², were positioned at the four outer sides of a sheet of Altuglas VSUVT 100 polymethylmethacrylate (PMMA) (dimensions 106×106×6 mm), obtained by the mass additivation of 100 ppm of 4,7-di-(thien-2′-yl)-2,1,3-benzothiadiazole (DTB) and subsequent “casting”.

The photovoltaic performance of said photovoltaic cells was measured with a solar simulator (Sun 2000 Solar Simulator of Abet Technologies) equipped with a 300 W xenon light source, the light intensity was calibrated by means of a standard silicon photovoltaic cell (“VLSI Standard” SRC-1000-RTD-KGS), the current-voltage characteristics were obtained by applying an external voltage to each of said cells and measuring the photocurrent generated with a digital multimeter “Keithley 2602A” (3 A DC, 10 A Pulse) obtaining the following result:
Jsc (short-circuit current density)=14.7 mA/cm².

### EXAMPLE 2

### Invention

Altuglas VSUVT 100 polymethylmethacrylate sheets (PMMA) (dimensions 106×6×6 mm), obtained by the mass additivation of 100 ppm of Lumogen® F Red 305 of Basf and subsequent “casting”, were positioned at the four sides of a sheet of Altuglas VSUVT 100 polymethylmethacrylate (PMMA) (dimensions 106×106×6 mm) obtained as described in Example 1.

Photovoltaic cells IXYS-XOD17 having a surface of 1.2 cm², were positioned at the smallest outer sides of each of said sheets.

The photovoltaic performance of said photovoltaic cells was measured with a solar simulator (Sun 2000 Solar Simulator of Abet Technologies) equipped with a 300 W xenon light source, the light intensity was calibrated by means of a standard silicon photovoltaic cell (“VLSI Standard” SRC-1000-RTD-KGS), the current-voltage characteristics were obtained by applying an external voltage to each of said cells and measuring the photocurrent generated with a digital multimeter “Keithley 2602A” (3 A DC, 10 A Pulse) obtaining the following result:
Jsc (short-circuit current density)=22.6 mA/cm².

From the result obtained, it can be seen that the Jsc (short-circuit current density) obtained in the presence of the light concentration device object of the present invention is about 54% higher with respect to that obtained by operating in the presence of a light concentration device of the known art (Example 1).

1. A light concentration device comprising:
a primary luminescent solar concentrator having at least one form selected from the group consisting of a polygon, a circle, and an ellipse, and comprising a photoluminescent compound having a first absorption range and a first emission range; and
a secondary luminescent solar concentrator positioned outside the primary luminescent solar concentrator, wherein the secondary luminescent solar concentrator comprises a photoluminescent compound having a second absorption range, which is superimposable to the first emission range and a second emission range.

2. The light concentration device according to claim 1, wherein the primary luminescent solar concentrator has a polygonal form, and the secondary luminescent solar concentrator is positioned outside a side of the primary luminescent solar concentrator.

3. The light concentration device according to claim 1, wherein the primary luminescent solar concentrator has a polygonal form, and the secondary luminescent solar concentrator is positioned outside more than one side of the primary luminescent solar concentrator.

4. The light concentration device according to claim 1, wherein the secondary luminescent solar concentrator envelops at least a part of an outer perimeter of the primary luminescent solar concentrator.

5. The light concentration device according to claim 1, wherein the primary luminescent solar concentrator comprises a matrix comprising at least one transparent material selected from the group consisting of a transparent polymer and a transparent glass.

6. The light concentration device according to claim 1, wherein the photoluminescent compound having a first absorption range and a first emission range has an absorption range of 290 nm to 700 nm and an emission range of 390 nm to 800 nm.

7. The light concentration device according to claim 1, wherein the photoluminescent compound having a first absorption range and a first emission range is at least one selected from the group consisting of a benzothiadiazole compound, an acene compound, and a mixture thereof.

8. The light concentration device according to claim 1, wherein the photoluminescent compound having a first absorption range and a first emission range is present in the primary luminescent solar concentrator in a quantity ranging from 0.1 g per surface unit to 2 g per surface unit, wherein the surface unit refers to a surface of the matrix of the primary luminescent solar concentrator comprising the at least one transparent material expressed in m².

9. The light concentration device according to claim 1, wherein the photoluminescent compound having a second absorption range and a second emission range has an absorption range of 400 nm to 700 nm and an emission range of 450 nm to 900 nm.

10. The light concentration device according to claim 1, wherein the secondary luminescent solar concentrator comprises a matrix comprising at least one transparent material selected from the group consisting of a transparent polymer and a transparent glass.

11. The light concentration device according to claim 1, wherein the matrix of the primary luminescent solar concentrator and the matrix of the secondary luminescent solar concentrator comprise the at least one transparent material.

12. The light concentration device according to claim 1, wherein the photoluminescent compound having a second absorption range and a second emission range is a perylene compound.

13. The light concentration device according to claim 1, wherein the photoluminescent compound having a second absorption range and a second emission range is present in the secondary luminescent solar concentrator in a quantity ranging from 0.1 g per surface unit to 2 g per surface unit, wherein the surface unit refers to a surface of the matrix of the secondary luminescent solar concentrator comprising the at least one transparent material expressed in m².

14. The light concentration device according to claim 1, wherein the secondary luminescent solar concentrator is positioned at a distance ranging from 0.5 μm to 3 mm with respect to the outer perimeter of the primary luminescent solar concentrator.

15. The light concentration device according to claim 1, wherein at least part of the outer perimeter of the primary luminescent solar concentrator is rough.

16. The light concentration device according to claim 1, further comprising a reflecting mirror positioned on at least part of an outer perimeter of the secondary luminescent solar concentrator.

17. A device comprising a light concentration device comprising:
a primary luminescent solar concentrator having at least one form selected from the group consisting of a polygon, a circle, and an ellipse, and comprising a photoluminescent compound having a first absorption range and a first emission range;
a secondary luminescent solar concentrator positioned outside the primary luminescent solar concentrator, wherein the secondary luminescent solar concentrator comprises a photoluminescent compound having a second absorption range, which is superimposable to the first emission range, and a second emission range; and
a cell positioned outside a smaller side of the secondary luminescent solar concentrator,
wherein the cell is a photovoltaic cell or a solar cell;
wherein the device is a photovoltaic device or a solar device.

18. The device according to claim 17, wherein the light concentration device is recited in claim 1.
